(19) United States
(12) Patent Application Publication
(10) Pub. No.: US 2023/0395577 A1
(43) Pub. Date: Dec. 7, 2023

(54) SOC-MEMORY INTEGRATION TO ACHIEVE SMALLEST AND THINNEST MEMORY ON PACKAGE ARCHITECTURE

(71) Applicant: Intel Corporation, Santa Clara, CA (US)

(72) Inventors: Eng Huat GOH, Ayer Itam (MY); Telesphor KAMGAING, Chandler, AZ (US); Jooi Wah WONG, Bukit Mertajam (MY); Min Suet LIM, Gelugor (MY); Chee Kheong YOON, Bayan Lepas (MY); Kavitha NAGARAJAN, Bangalore (IN); Chu Aun LIM, Hillsboro, OR (US)

(21) Appl. No.: 17/833,592

(22) Filed: Jun. 6, 2022

(51) Int. Cl. H01L 25/10; H01L 25/065; H01L 25/00

(52) U.S. Cl. CPC H01L 25/105; H01L 25/0657; H01L 25/50; H01L 2225/0651; H01L 2225/06562; H01L 2225/06586

(57) ABSTRACT

Embodiments disclosed herein include an electronic package. In an embodiment, the electronic package comprises a package substrate with a cutout. In an embodiment, pads are adjacent to the cutout. In an embodiment, a memory die stack is on the package substrate, where the memory die stack is electrically coupled to the pads by routing in the package substrate. In an embodiment, a die is over the cutout, where the die is supported by the pads.

### TECHNICAL FIELD

Embodiments of the present disclosure relate to electronic packages, and more particularly to packaging architectures that include memory stacks embedded in a mold layer and a die that spans across a package substrate opening.

### BACKGROUND

Memory on package (MoP) architectures have been used in order achieve the best DDR performance and smallest SoC XY footprint. However, there are a few intrinsic issues that arise with existing MoP architectures. On issue is an increased Z-height. The addition of a tall memory package (e.g., a stack of memory dies on a memory package substrate) increases the Z-height of the device. For example, Z-heights may be increased by between 300 μm and 350 μm in some architectures. In some instances, the increase in the Z-height is mitigated by using a coreless package architecture. However, the use of a coreless architecture is an extremely expensive solution.

Additionally, the MoP architecture results in an overall SoC package XY form factor that is substantially large. This is due to the need to include a stiffener in order to control warpage of the package substrate. In some instances, a combination stiffener and integrated heat spreader (IHS) is used in order to control warpage and improve thermal performance. However, such architectures are expensive solutions.

### BRIEF DESCRIPTION OF THE DRAWINGS

FIG. 1 is a cross-sectional illustration of a memory on package (MoP) architecture where the memory die stacks are provided on a package substrate that is connected to the main package substrate.

FIG. 2 is a cross-sectional illustration of an electronic package with memory die stacks directly on the package substrate and a die that spans across a cutout in the package substrate, in accordance with an embodiment.

FIG. 3A is a plan view illustration of an electronic package with memory die stacks on the package substrate with a cutout in the package substrate, in accordance with an embodiment.

FIG. 3B is a plan view illustration of an electronic package with memory die stacks embedded in a ring-shaped mold layer and a cutout in the package substrate, in accordance with an embodiment.

FIG. 3C is a cross-sectional illustration of an electronic package with memory die stacks embedded in a mold layer, and a cutout in the package substrate, in accordance with an embodiment.

FIG. 4A is a cross-sectional illustration of a package substrate with a cutout, in accordance with an embodiment.

FIG. 4B is a cross-sectional illustration of the package substrate with memory die stacks directly coupled to the package substrate, in accordance with an embodiment.

FIG. 4C is a cross-sectional illustration of the package substrate after a mold layer is formed around the memory die stacks, in accordance with an embodiment.

FIG. 4D is a cross-sectional illustration of a die that is to be attached to the package substrate, in accordance with an embodiment.

FIG. 4E is a cross-sectional illustration of the die after conductive pillars are formed on die pads, in accordance with an embodiment.

FIG. 4F is a cross-sectional illustration of the die after a mold layer is provided around the pillars, in accordance with an embodiment.

FIG. 4G is a cross-sectional illustration of the die after a redistribution layer is formed on the mold layer, in accordance with an embodiment.

FIG. 4H is a cross-sectional illustration of the electronic package after the die is attached to the package substrate, in accordance with an embodiment.

FIG. 5 is a cross-sectional illustration of an electronic system with a die that spans a cutout in a package substrate that is coupled to a board, in accordance with an embodiment.

FIG. 6 is a schematic of a computing device built in accordance with an embodiment.

### EMBODIMENTS OF THE PRESENT DISCLOSURE

Described herein are packaging architectures that include memory stacks embedded in a mold layer and a die that spans across a package substrate opening, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

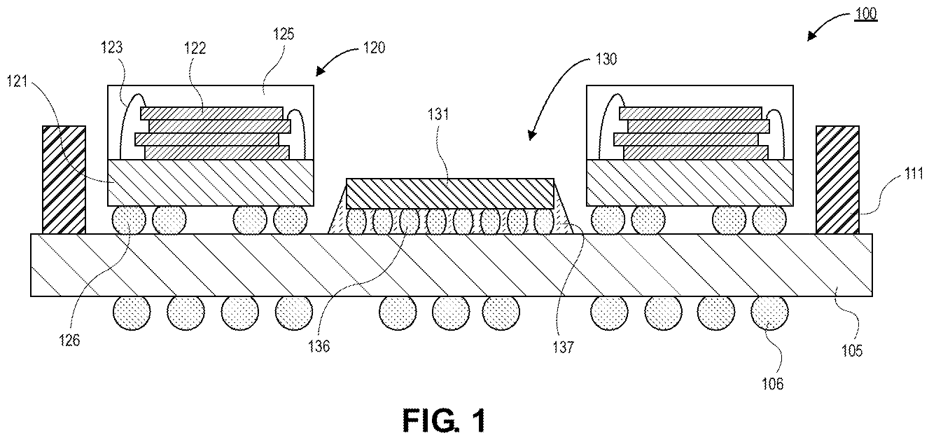

FIG. 1 is a cross-sectional illustration of an electronic package 100 used to provide context for embodiments described herein. The electronic package 100 includes an architecture where memory die stacks 120 are attached to a package substrate 105 adjacent to a die module 130. The package substrate 105 may include bumps 106 on a backside of the package substrate 105. The memory die stacks 120 and the die module 130 may be provided on the front side of the package substrate 105. For example, the memory die stack 120 may include bumps 126 that connect to the package substrate 105, and the die module 130 may include bumps 136 that connect to the package substrate 105. An underfill 137 may be provided around the bumps 136. While not shown, an underfill may also surround the bumps 126 between the memory die stack 120 and the package substrate 105.

The die module 130 may include any number of dies 131 in any architecture. For example, a single die 131 is shown in FIG. 1. In other embodiments, the die module 130 may include multiple dies coupled together by an interposer or the like. The die module 130 may be a system on a chip (SoC) or any other type of die or dies. The die module 130 may be communicatively coupled to the memory die stacks 120 through routing (not shown) on and/or in the package substrate 105.

The memory die stacks 120 may include a memory package substrate 121. A stack of memory dies 122 may be provided over the memory package substrate 121. The memory dies 122 may be electrically coupled to the memory package substrate 121 through wire bonds 123. Due to the presence of the memory package substrate 121, the length of the routing from the memory dies 122 to the die module 130 is long. This leads to larger delays and signal integrity issues. Additionally, the memory package substrate 121 results in an increase in the Z-height of the electronic package 100. A stiffener 111 may also be needed in order to mitigate warpage issues. The presence of the stiffener 111 increase the X-Y dimensions of the electronic package 100.

Accordingly, memory on package (MoP) architectures, such as the one shown in FIG. 1, have intrinsic drawbacks, such as increased Z-height and increased X-Y form factor. Additionally signal integrity issues may arise due to long interconnect lengths. Accordingly, embodiments disclosed herein include MoP architectures that have a smaller Z-height and reduced XY form factor. Such architectures may also be made without relying on coreless package substrates. Accordingly, the solutions described herein are cost effective architectures as well. The interconnect length between the die module 130 and the memory die stacks 120 is also reduced.

Particularly, a package substrate is provided and memory die stacks are provided directly on the package substrate. The memory dies 122 may be coupled to the package substrate 105 directly through wire bonds 123. As such, there is no need for a memory package substrate 121 between the memory dies 122 and the main package substrate 105. This results in a decrease in the Z-height of the device. Additionally, the XY form factor is reduced by the use of mold layer 125 around the memory die stacks 120. The mold layer 125 allows for the elimination of the stiffener 111 in some embodiments. That is, the mold layer 125 improves the stiffness of the package substrate 105, and there may not be a need for a stiffener. Additionally, Z-height is further reduced by spanning a die across an opening through the package substrate 105. A mold layer 125 with conductive pillars may electrically couple die pads to solder balls below the package substrate 105.

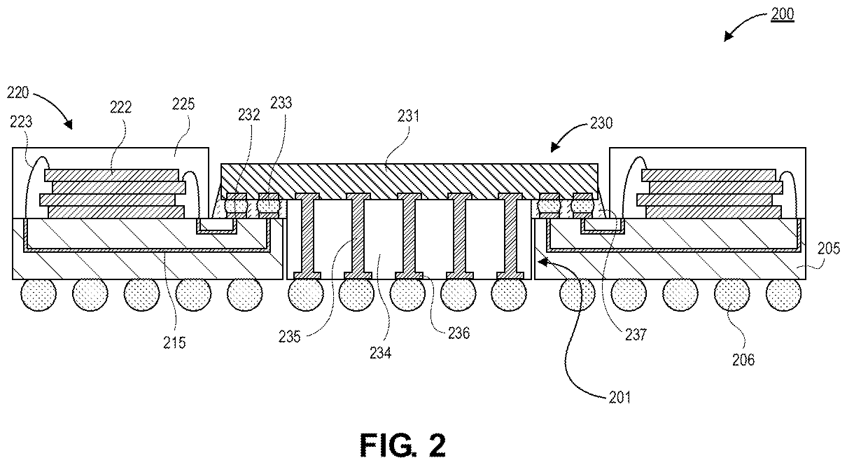

Referring now to FIG. 2, a cross-sectional illustration of an electronic package 200 is shown, in accordance with an embodiment. In an embodiment, the electronic package 200 may have a package substrate 205 with a core (not shown). Routing layers may be provided above and below the core. For example, routing 215 is shown in FIG. 2. The routing 215 may include traces, pads, vias, and the like. Routing layers may be separated from each other by buildup layers, as is common in the art of semiconductor packaging. In an embodiment, three or more routing layers, four or more routing layers, or five or more routing layers may be provided on each side of the core.

In an embodiment, the package substrate 205 may include a cutout 201. The cutout 201 may be located at a center of the package substrate 205. The cutout 201 is a cavity that passes entirely through a thickness of the package substrate 205. For example, the cutout 201 may sometimes be referred to as a through hole, a hole, or the like. The sidewalls of the cutout 201 may be substantially vertical. The cutout 201 may be formed with a mechanical drilling process, a laser drilling process, or the like. In FIG. 2, the cross-section illustrates that there is a left side of the package substrate 205 and a right side of the package substrate 205. It is to be appreciated that the left side and the right side are mechanically coupled together by portions of the package substrate 205 outside of the plane shown in FIG. 2.

In an embodiment, one or more memory die stacks 220 may be provided over the package substrate 205. The memory die stacks 220 may comprise a stack of one or more memory dies 222. For example, a set of four memory dies 222 are shown in the memory die stacks 220. The memory dies 222 may be arranged in an offset pattern. As such, top surfaces of each memory die 222 are exposed. This allows for wire bonds 223 to be provided from each memory die 222 to the package substrate 205. Pads (not shown) may be on the package substrate 205 side of the wire bonds 223. As shown, the wire bonds 223 may be electrically coupled to the routing 215 within the package substrate 205.

In an embodiment, the memory die stacks 220 may also include a mold layer 225. The mold layer 225 may embed the memory dies 222 and the wire bonds 223. The mold layer 225 may also be a ring shaped layer that is provided around a perimeter of the package substrate 205. The mold layer 225 may increase the stiffness of the package substrate 205. As such, there may not be a need for a stiffener or the like. As such, space in the XY plane can be saved, and the form factor of the electronic package is reduced.

In an embodiment, the electronic package 200 may further comprise a die module 230. In an embodiment, the die module 230 may include one or more dies 231. The dies 231 may be compute dies, an SoC, or any other type of die. While a single die 231 is shown in FIG. 2, it is to be appreciated that multiple dies 231 may be coupled together by an interposer or the like. In such an embodiment, the interposer may be coupled to the package substrate 205 instead of the dies 231.

In an embodiment, the die 231 spans across the cutout 201. As shown, the die 231 is supported from below by pads 232 that are adjacent to the cutout 201. The die 231 may be coupled to the pads 232 by solder balls 233 or other interconnect architectures. In an embodiment, the pads 232 may be electrically coupled to the routing 215 in the package substrate 205. As such, the memory die stacks 220 are electrically coupled to the die 231 through the routing 215, the pads 232, and the solder balls 233. In an embodiment, the solder balls 233 may be surrounded by an underfill 237, such as a capillary underfill (CUF) material.

In an embodiment, the die module 230 may also include a mold layer 234. The mold layer 234 may be provided below the die 231. The mold layer 234 may pass through a thickness of the cutout 201. That is, the mold layer 234 may be thicker than the package substrate 205 in some embodiments. In an embodiment, conductive pillars 235 may pass through the mold layer 234. The conductive pillars 235 may be copper or the like. In an embodiment, the pillars 235 may terminate at pads 236. The pads 236 may be part of a redistribution layer (not shown) in some embodiments. The pads 236 may have interconnects 206 on the bottom surface, such as solder balls or the like. The interconnects 206 may also be provided over the backside of the package substrate 205.

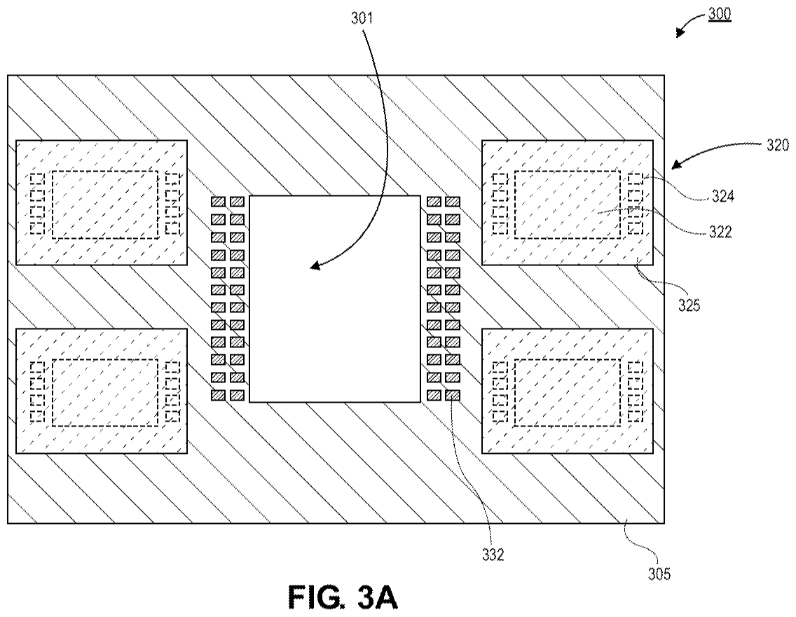

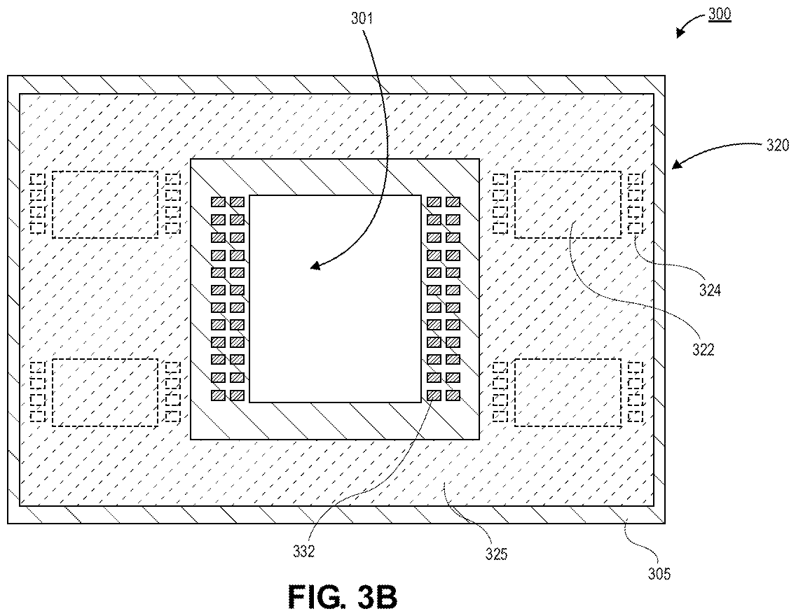

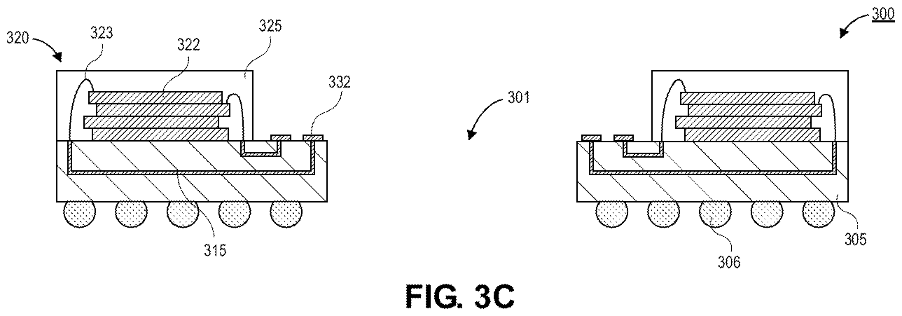

Referring now to FIG. 3A, a plan view illustration of an electronic package 300 is shown, in accordance with an embodiment. In an embodiment, the electronic package 300 is shown without a die module in order to not obscure aspects of the disclosure. However, it is to be appreciated that a die module similar to the die module 230 described above may span across the cutout 301. As shown, the cutout 301 is rectangular and portions of the package substrate 305 surround an entire perimeter of the cutout 301. That is, the cutout 301 may be at a middle of the package substrate 305 instead of being at an edge of the package substrate 305.

In an embodiment, a plurality of memory die stacks 320 are provided on the package substrate 305. For example, a set of four memory die stacks 320 are shown in FIG. 3A. Though, it is to be appreciated that embodiments may include one or more memory die stacks 320. The memory die stacks 320 may include a stack of one or more memory dies 322. The memory dies 322 may be coupled to pads 324 by wire bonds (not shown). The memory dies 322 and the pads 324 are shown with dashed outlines in order to indicate that they are embedded within the mold layer 325. As shown, in FIG. 3A, each memory die stack 320 may be surrounded by a discrete mold layer 325. However, in other embodiments, a single mold layer 325 may surround each of the memory die stacks 320, as will be described in greater detail below.

In an embodiment, a plurality of pads 332 may be provided adjacent to the cutout 301. Two columns of pads 332 are provided on each side of the cutout 301 in FIG. 3A. However, it is to be appreciated that any number of columns may be used. Additionally, in some embodiments, pads 332 may also be provided above and below the cutout 301. The pads 332 may be electrically coupled to the pads 324 through routing in the package substrate 305, such as the routing 215 described in greater detail above. Since there is no memory die stack package substrate (as is shown in FIG. 1) the conductive routing may be reduced in length. For example, the routing from the pads 324 to the pads 332 may be approximately 20 mm or less in length. As used herein, “approximately” may refer to a range of values that is within 10% of the stated value. For example, approximately 20 mm may include a range from 18 mm to 22 mm. This improves signal integrity and minimizes any delays in the signaling to and from the memory die stacks 320.

Referring now to FIG. 3B, a plan view illustration of an electronic package 300 is shown, in accordance with an additional embodiment. In an embodiment, the electronic package 300 may be substantially similar to the electronic package 300 described above with respect to FIG. 3A, with the exception of the structure of the mold layer 325. Instead of having discrete portions of the mold layer 325 around each of the memory die stacks 320, a single mold layer 325 is provided over all of the memory die stacks 320. In some instances, the mold layer 325 may be ring shaped. That is, the mold layer 325 may have an inner surface and an outer surface. In the illustrated embodiment, the inner surface and the outer surface form rectangular shapes.

In an embodiment, the inner surface of the mold layer 325 may be sized to expose the pads 332. For example, a die module (not shown) may set onto the package substrate 305 within the mold layer 325. In other words, the mold layer 325 may surround an outer perimeter of the die module. When the mold layer 325 is in a ring shape, the electronic package 300 may omit a stiffener. This is because the mold layer 325 has a high stiffness and is mechanically coupled to the package substrate 305. As such, the mold layer 325 functions as the stiffener. This allows for space in the XY dimension to be saved and reduces the form factor of the electronic package 300.

Referring now to FIG. 3C, a cross-sectional illustration of the electronic package 300 in FIG. 3B is shown, in accordance with an embodiment. As shown, the cutout 301 pass through an entire thickness of the package substrate 305. Additionally, the routing 315 between the pads 332 and the wire bonds 323 is shown. In an embodiment, the routing 315 may be provided in one or more routing layers above a top surface of the core (not shown). Some of the wire bonds 323 may also be electrically coupled to interconnects 306 on the bottom of the package substrate 305. The routing through the thickness of the package substrate 305 is not shown in FIG. 3C.

In the illustrated embodiment, the mold layer 325 extends to an edge of the package substrate 305. In other embodiments, the outer edge of the mold layer 325 may be inset from the outer edge of the package substrate 305, similar to the embodiments shown in FIG. 3B. The inner edge of the mold layer 325 may be inset from an edge of the pads 332. As such, a die module (not shown) may be set onto the pads 332 within a perimeter of the mold layer 325.

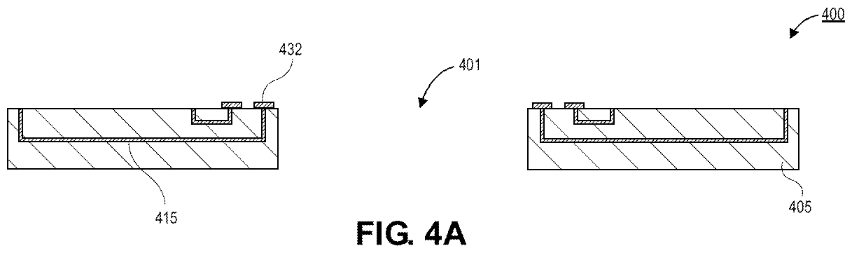

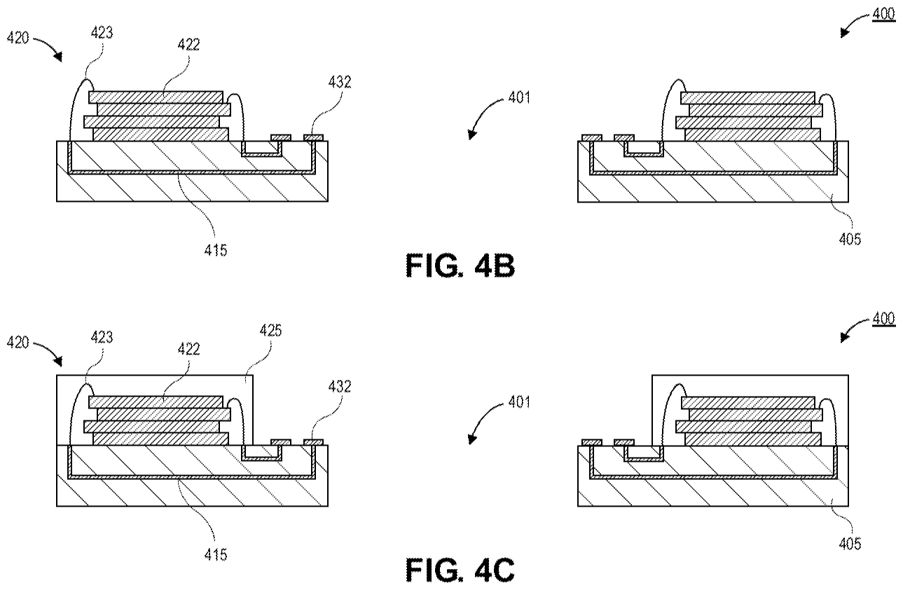

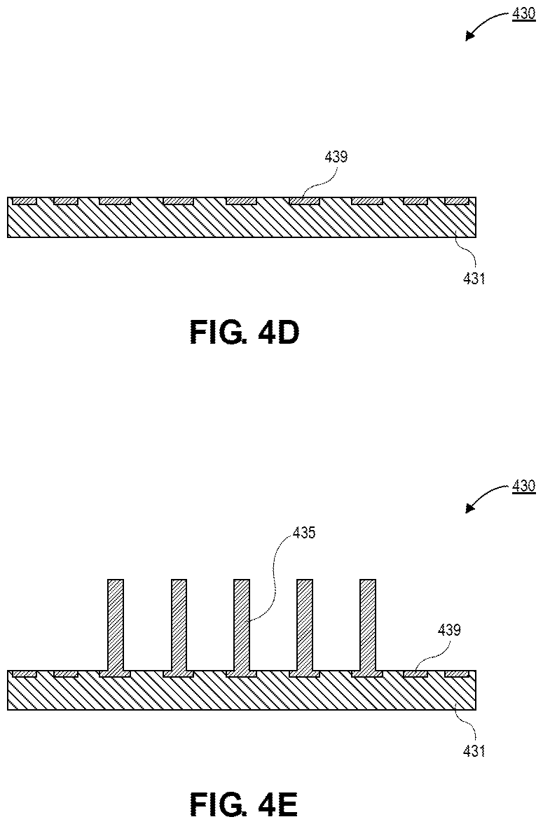

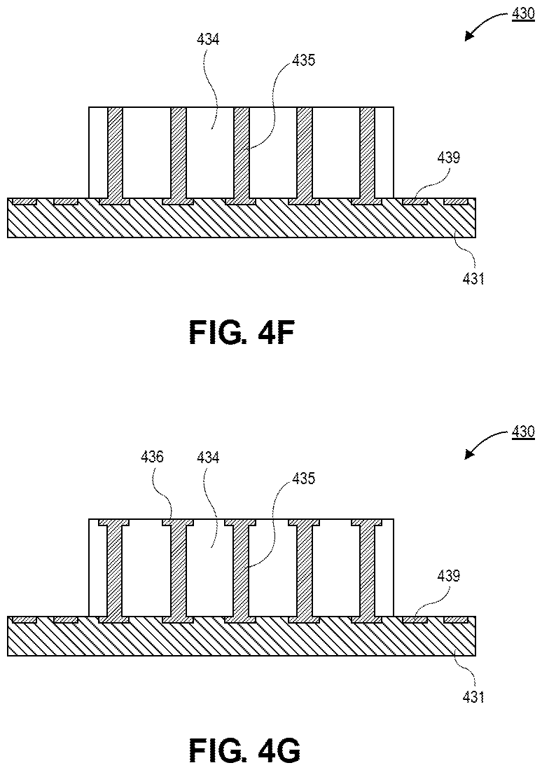

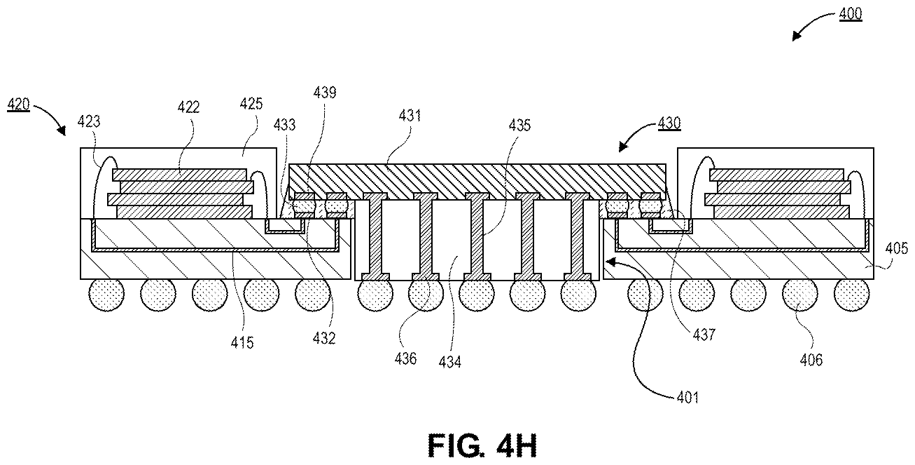

Referring now to FIGS. 4A-4H, a series of cross-sectional illustrations depicting a process for forming an electronic package 400 is shown, in accordance with an embodiment. FIGS. 4A-4C are illustrations of a process for assembling the memory die stacks 420 to the package substrate 405. FIGS. 4D-4G are illustrations of a process for assembling the die module 430, and FIG. 4H is an illustration of the die module 430 coupled to the package substrate 405.

Referring now to FIG. 4A, a cross-sectional illustration of an electronic package 400 in a stage of fabrication is shown, in accordance with an embodiment. In an embodiment, the electronic package 400 may comprise a package substrate 405. The package substrate 405 may be a cored package substrate. In an embodiment, conductive routing 415 may be provided in one or more routing layers of the package substrate 405. The conductive routing 415 may provide electrical coupling from wire bonds (added in a subsequent processing operation) to pads 432. The pads 432 are subsequently coupled to the die module 430 (not shown in FIG. 4A).

In an embodiment, a cutout 401 is provided through a thickness of the package substrate 405. In an embodiment, the cutout 401 is surrounded on all sides by the package substrate 405. That is, the left portion of the package substrate 405 and the right portion of the package substrate 405 are coupled together by portions of the package substrate 405 outside of the plane of FIG. 4A. In an embodiment, the pads 432 are adjacent to the cutout 401.

Referring now to FIG. 4B, a cross-sectional illustration of the electronic package 400 after the memory die stacks 420 are attached to the package substrate 405 is shown, in accordance with an embodiment. In an embodiment, the memory die stacks 420 may include one or more memory dies 422. For example, four memory dies 422 are provided in each of the memory die stacks 420 in FIG. 4B. The bottommost memory die 422 may be directly contacting the package substrate 405. In some embodiments, an adhesive (e.g., die attach film (DAF)) may be provided between the bottommost memory die 422 and the package substrate 405. Particularly, it is noted that there is no intermediary package substrate between the dies 422 and the package substrate 405. This reduces the Z-height of the electronic package 400. For example, the removal of the intermediary package substrate may result in a Z-height savings of 300 μm or more or 350 μm or more.

The memory dies 422 may be arranged in an offset pattern. The offset pattern allows for a top surface of each of the memory dies 422 to be accessible in order to attach wire bonds 423. In the illustrated embodiment, the wire bonds 423 are directly contacting the routing 415. In other embodiments, pads (not shown) may be provided between the wire bonds 423 and the routing 415.

Referring now to FIG. 4C, a cross-sectional illustration of the electronic package 400 after a mold layer 425 is formed is shown, in accordance with an embodiment. In an embodiment, the mold layer 425 may be provided over and around the memory die stacks 420. That is, the mold layer 425 may embed the memory die stacks 420 in some embodiments. A single mold layer 425 may be provided over each of the memory die stacks 420. For example, in FIG. 4C, the left mold layer 425 and the right mold layer 425 may be connected to each other by portions of the mold layer 425 outside of the plane of FIG. 4C. In such an embodiment, the mold layer 425 may function as a stiffener to the package substrate 405. As such, a dedicated stiffener may not be necessary and space in the XY plane can be saved to reduce the form factor of the electronic package 400. In other embodiments, discrete mold layers 425 may be provided over each of the memory die stacks 420.

Referring now to FIG. 4D, a cross-sectional illustration of a portion of a die module 430 is shown, in accordance with an embodiment. In an embodiment, the die module 430 may include one or more dies 431. In the illustrated embodiment, a single die 431 is shown. The die 431 may be a compute die, such as a central processing unit (CPU), graphics processing unit (GPU), an SoC, or any other type of die or dies. In embodiments with multiple dies, an interposer or the like may be used to couple the plurality of dies together. In an embodiment, pads 439 may be provided on a surface of the die 431.

Referring now to FIG. 4E, a cross-sectional illustration of a portion of the die module 430 after conductive pillars 435 are formed is shown, in accordance with an embodiment. In an embodiment, the conductive pillars 435 may comprise copper or the like. The conductive pillars 435 may be formed with any suitable assembly process. For example, a photoresist layer may be deposited and patterned to form openings. The conductive pillars 435 may then be plated in the openings and the photoresist is removed. As shown in FIG. 4E, not all of the pads 439 have pillars 435 formed over them. Particularly, the outer two pads 439 on each side of the die 431 do not have pillars 435. In other embodiments one or more rows of pads 439 on each side may not have pillars 435. The pads 439 without pillars 435 will ultimately be coupled to the pads 432 on the package substrate 405.

Referring now to FIG. 4F, a cross-sectional illustration of a portion of the die module 430 after a mold layer 434 is provided around the pillars 435 is shown, in accordance with an embodiment. In an embodiment, the mold layer 434 may be formed with any suitable molding process. For example, the mold layer 434 may be an epoxy mold material or the like. In an embodiment, the mold layer 434 is selectively formed in order to only cover the pillars 435. That is, the outer pads 439 without the pillars 435 do not have mold material disposed over them.

Referring now to FIG. 4G, a cross-sectional illustration of the die module 430 after pads 436 are formed at the top of the pillars 435 is shown, in accordance with an embodiment. In an embodiment, the pads 436 may be part of a redistribution layer (not shown). The redistribution layer allows for the positioning of the pads 439 on the die 431 to be redistributed in order to match any desired bumping pattern. In an embodiment, multiple redistribution layers may be formed over the top of the mold layer 434.

Referring now to FIG. 4H, a cross-sectional illustration of the electronic package 400 after the die module 430 is attached to the package substrate 405 is shown, in accordance with an embodiment. In an embodiment, the die module 430 may be attached to the package substrate 405 so that the die 431 extends across the cutout 401. As shown, the die 431 is supported from below by the pads 432. That is, pads 439 of the die 431 (which do not include pillars 435) are coupled to the pads 432 on the package substrate 405. As shown, the routing 415 may electrically couple the die module 430 to the memory die stacks 420. Solder balls 433 may be used to couple the pads 439 to the pads 432. In some embodiments, an underfill layer 437 may surround the solder balls 433.

In an embodiment, the die module 430 may be positioned so that the mold layer 434 and the pillars 435 pass through a thickness of the cutout 401. As shown, the bottom of the mold layer 434 may be substantially coplanar with the bottom surface of the package substrate 405. Though in other embodiments, the bottom of the mold layer 434 may be above or below the bottom surface of the package substrate 405. In an embodiment, interconnects 406 (e.g., solder balls or the like) may be provided on the bottom surface of the package substrate 405 and the pads 436 of the pillars 435.

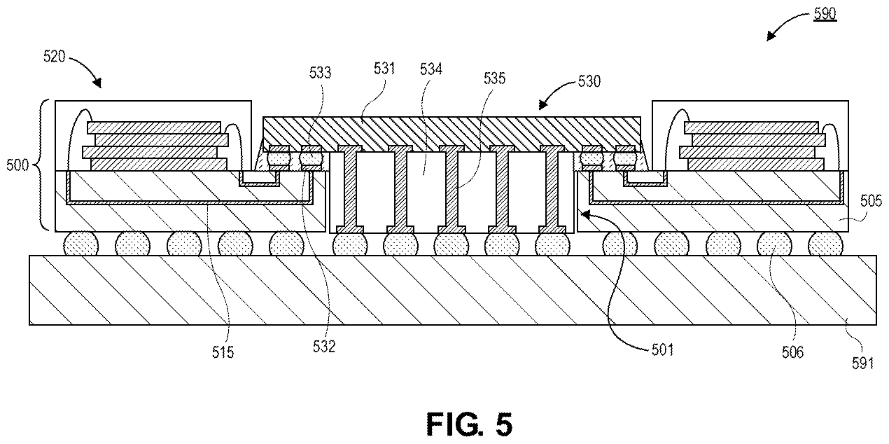

Referring now to FIG. 5, a cross-sectional illustration of an electronic system 590 is shown, in accordance with an embodiment. In an embodiment, the electronic system 590 may include a board 591, such as a printed circuit board (PCB). In an embodiment, an electronic package 500 may be coupled to the board 591 by interconnects 506, such as solder balls or the like. In the illustrated embodiment, the electronic package 500 is substantially similar to the electronic package 400 shown in FIG. 4H. However, it is to be appreciated that any electronic package architecture disclosed herein may be used in the electronic system 590.

In an embodiment, the electronic package 500 may include a package substrate 505 with a cutout 501. The package substrate 500 may also include a memory die stack 520 and a die module 530. The memory die stack 520 may be electrically coupled to the die module 530 by routing 515 in the package substrate 505. The routing 515 may terminate at pads 532. Pads 532 of the package substrate 505 may be coupled to the die by interconnects 533. The die module 530 may include a die 531 with pillars 535 surrounded by a mold layer 534. The pillars 535 and the mold layer 534 may pass through a thickness of the cutout 501.

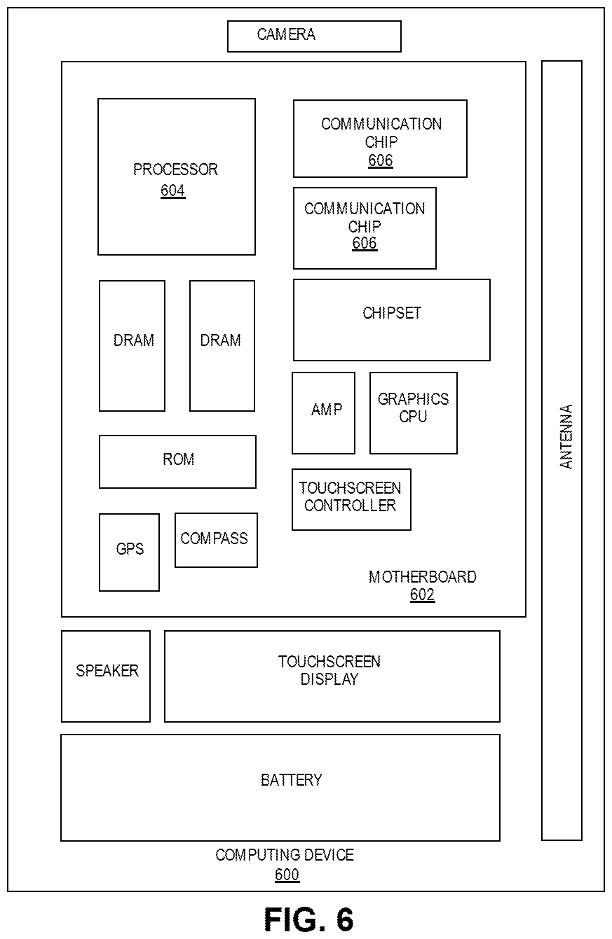

FIG. 6 illustrates a computing device 600 in accordance with one implementation of the invention. The computing device 600 houses a board 602. The board 602 may include a number of components, including but not limited to a processor 604 and at least one communication chip 606. The processor 604 is physically and electrically coupled to the board 602. In some implementations the at least one communication chip 606 is also physically and electrically coupled to the board 602. In further implementations, the communication chip 606 is part of the processor 604.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 606 enables wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

The processor 604 of the computing device 600 includes an integrated circuit die packaged within the processor 604. In some implementations of the invention, the integrated circuit die of the processor may be part of an electronic package with a cutout that includes memory die stacks and a die module that extends across the cutout, in accordance with embodiments described herein. The term “processor” may refer to any device or portion of a device that processes electronic data from registers and/or memory to transform that electronic data into other electronic data that may be stored in registers and/or memory.

The communication chip 606 also includes an integrated circuit die packaged within the communication chip 606. In accordance with another implementation of the invention, the integrated circuit die of the communication chip may be part of an electronic package with a cutout that includes memory die stacks and a die module that extends across the cutout, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: an electronic package, comprising: a package substrate with a cutout; pads adjacent to the cutout; a memory die stack on the package substrate, wherein the memory die stack is electrically coupled to the pads by routing in the package substrate; and a die over the cutout, wherein the die is supported by the pads.

Example 2: the electronic package of Example 1, wherein the memory die stack is embedded in a mold layer.

Example 3: the electronic package of Example 1 or Example 2, further comprising: pillars that extend from a surface of the die through the cutout.

Example 4: the electronic package of Example 3, further comprising: a mold layer around the pillars.

Example 5: the electronic package of Example 4, wherein a redistribution layer is provided on a surface of the mold layer opposite from the die.

Example 6: the electronic package of Examples 1-5, wherein the die is coupled to the pads by solder balls.

Example 7: the electronic package of Examples 1-6, further comprising: a plurality of memory die stacks coupled to the package substrate, wherein the plurality of memory die stacks are electrically coupled to the pads by routing in the package substrate.

Example 8: the electronic package of Example 7, wherein a mold layer is provided around the plurality of memory die stacks.

Example 9: the electronic package of Example 8, wherein the mold layer is ring shaped.

Example 10: the electronic package of Examples 1-9, wherein the memory die stack is electrically coupled to the package substrate by wire bonds.

Example 11: the electronic package of Examples 1-10, wherein the memory die stack comprises four or more memory dies.

Example 12: the electronic package of Examples 1-11, wherein the routing in the package substrate is approximately 20 mm in length of shorter.

Example 13: a method of forming an electronic package, comprising: providing a package substrate with a cutout, wherein pads on the package substrate are adjacent to the cutout; attaching a memory die stack to the package substrate; forming a mold layer over the memory die stack; and attaching a die to the package substrate, wherein the die spans across the cutout.

Example 14: the method of Example 13, wherein the memory die stack is electrically coupled to the package substrate by wire bonds.

Example 15: the method of Example 13 or Example 14, wherein the die comprises pillars, wherein the pillars pass through the cutout.

Example 16: the method of Example 15, wherein a second mold layer is disposed around the pillars.

Example 17: the method of Example 16, wherein a redistribution layer is provided on the second mold layer.

Example 18: the method of Examples 13-17, wherein the die is electrically coupled to the pads on the package substrate.

Example 19: the method of Example 18, wherein the memory die stack is electrically coupled to the pads on the package substrate by routing in the package substrate.

Example 20: the method of Example 18 or Example 19, further comprising: attaching a plurality of memory die stacks to the package substrate.

Example 21: the method of Example 20, wherein the mold layer is formed over the plurality of memory die stacks.

Example 22: the method of Example 21, wherein the mold layer is ring shaped.

Example 23: an electronic system, comprising: a board; a package substrate coupled to the board, wherein the package substrate comprises a cutout; a memory die stack attached to the package substrate; a mold layer around the memory die stack; and a die that spans across the cutout.

Example 24: the electronic system of Example 23, wherein the die is coupled to the board by pillars that extend through a second mold layer between the die and the board.

Example 25: the electronic system of Example 23 or Example 24, wherein the die is coupled to pads on the package substrate, and wherein the pads are coupled to the memory die stack through routing in the package substrate.

What is claimed is:

1. An electronic package, comprising:
a package substrate with a cutout;
pads adjacent to the cutout;
a memory die stack on the package substrate, wherein the memory die stack is electrically coupled to the pads by routing in the package substrate; and
a die over the cutout, wherein the die is supported by the pads.

2. The electronic package of claim 1, wherein the memory die stack is embedded in a mold layer.

3. The electronic package of claim 1, further comprising:
pillars that extend from a surface of the die through the cutout.

4. The electronic package of claim 3, further comprising:
a mold layer around the pillars.

5. The electronic package of claim 4, wherein a redistribution layer is provided on a surface of the mold layer opposite from the die.

6. The electronic package of claim 1, wherein the die is coupled to the pads by solder balls.

7. The electronic package of claim 1, further comprising:
a plurality of memory die stacks coupled to the package substrate, wherein the plurality of memory die stacks are electrically coupled to the pads by routing in the package substrate.

8. The electronic package of claim 7, wherein a mold layer is provided around the plurality of memory die stacks.

9. The electronic package of claim 8, wherein the mold layer is ring shaped.

10. The electronic package of claim 1, wherein the memory die stack is electrically coupled to the package substrate by wire bonds.

11. The electronic package of claim 1, wherein the memory die stack comprises four or more memory dies.

12. The electronic package of claim 1, wherein the routing in the package substrate is approximately 20 mm in length of shorter.

13. A method of forming an electronic package, comprising:
providing a package substrate with a cutout, wherein pads on the package substrate are adjacent to the cutout;
attaching a memory die stack to the package substrate;
forming a mold layer over the memory die stack; and
attaching a die to the package substrate, wherein the die spans across the cutout.

14. The method of claim 13, wherein the memory die stack is electrically coupled to the package substrate by wire bonds.

15. The method of claim 13, wherein the die comprises pillars, wherein the pillars pass through the cutout.

16. The method of claim 15, wherein a second mold layer is disposed around the pillars.

17. The method of claim 16, wherein a redistribution layer is provided on the second mold layer.

18. The method of claim 13, wherein the die is electrically coupled to the pads on the package substrate.

19. The method of claim 18, wherein the memory die stack is electrically coupled to the pads on the package substrate by routing in the package substrate.

20. The method of claim 18, further comprising:
attaching a plurality of memory die stacks to the package substrate.

21. The method of claim 20, wherein the mold layer is formed over the plurality of memory die stacks.

22. The method of claim 21, wherein the mold layer is ring shaped.

23. An electronic system, comprising:
a board;
a package substrate coupled to the board, wherein the package substrate comprises a cutout;
a memory die stack attached to the package substrate;
a mold layer around the memory die stack; and
a die that spans across the cutout.

24. The electronic system of claim 23, wherein the die is coupled to the board by pillars that extend through a second mold layer between the die and the board.

25. The electronic system of claim 23, wherein the die is coupled to pads on the package substrate, and wherein the pads are coupled to the memory die stack through routing in the package substrate.
